(19) United States
(12) Patent Application Publication
(10) Pub. No.: US 2014/0251209 A1
(43) Pub. Date: Sep. 11, 2014

(54) SUPPORT MEMBER AND SEMICONDUCTOR MANUFACTURING APPARATUS

(71) Applicant: Tokyo Electron Limited, Tokyo (JP)

(72) Inventors: Tomoyuki OBU, Nirasaki City (JP); Masaki KUROKAWA, Nirasaki City (JP); Hiroki IRIUDA, Nirasaki City (JP); Ken ITABASHI, Oshu-shi (JP); Yasushi TAKEUCHI, Oshu-shi (JP)

(73) Assignee: TOKYO ELECTRON LIMITED, Tokyo (JP)

(21) Appl. No.: 14/202,587

(22) Filed: Mar. 10, 2014

(30) Foreign Application Priority Data
Mar. 11, 2013 (JP) 2013-047514

(51) Int. Cl. H01L 21/673

(52) U.S. Cl. CPC H01L 21/673
USPC 118/500

(57) ABSTRACT

A support member includes: a mounting unit having a first main surface and a second main surface, the first main surface being configured to mount a first object to be processed thereon and the second main surface being configured to mount a second object to be processed thereon; and a wall installed in a part of the outer peripheral portion along the outer periphery of the mounting unit, the wall having a first portion protruding in a vertical direction than the first object to be processed mounted on the first main surface of the mounting unit. The inner peripheral surface of the first portion of the wall is formed in a first shape that allows the first object to be processed to be held by the first portion of the wall.

### CROSS-REFERENCE TO RELATED APPLICATION

This application claims the benefit of Japanese Patent Application No. 2013-047514, filed on Mar. 11, 2013, in the Japan Patent Office, the disclosure of which is incorporated herein in their entirety by reference.

### TECHNICAL FIELD

The present disclosure relates to a support member and a semiconductor manufacturing apparatus.

### BACKGROUND

Conventionally, in a manufacturing process of a semiconductor device or the like, a film formation process is performed on a silicon substrate using a vertical furnace. In such a manufacturing apparatus, due to its structure, substantially the same type of film may adhere to both front and rear surfaces of the silicon substrate. As a method of avoiding the adhesion of the film to both surfaces of the silicon substrate, for example, there has been provided a method of bonding rear surfaces of two substrates to a front surface and a rear surface of a support member, respectively. This allows the film to be formed only on the front surfaces of the two substrates, respectively.

However, when a heat treatment is performed on the silicon substrates supported by a substrate support member of a vertical furnace while two substrates are bonded to the front and rear surfaces of the substrate support member, the silicon substrates may be bent due to the thermal expansion of the silicon substrates. In particular, due to the additional influence of the gravity, it is likely that heavy bending (drooping) occurs in the substrate bonded to the rear surface of the substrate support member. Therefore, there is a problem in that wraparound of the film formation may occur on the rear surface of the bent substrate.

### SUMMARY

The present disclosure provides some embodiments of a support member capable of preventing bending of substrates during heat treatment, particularly, during film formation, and a semiconductor manufacturing apparatus having the same.

According to a first aspect of the present disclosure, there is provided a support member including: a mounting unit having a first main surface and a second main surface, the first main surface being configured to mount a first object to be processed thereon and the second main surface being configured to mount a second object to be processed thereon; and a wall installed in a part of the outer peripheral portion along the outer periphery of the mounting unit, the wall having a first portion protruding in a vertical direction than the first object to be processed mounted on the first main surface of the mounting unit, wherein the inner peripheral surface of the first portion of the wall is formed in a first shape that allows the first object to be processed to be held by the first portion of the wall.

According to a second aspect of the present disclosure, there is provided a semiconductor manufacturing apparatus including: the support member of the first aspect; and a holding member configured to hold the support member, the holding member having an opening through which the supported member is inserted into the holding member.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a semiconductor manufacturing apparatus according to an embodiment of the present disclosure.

FIG. 2 is a view illustrating a structure of a wafer boat.

FIG. 3 is a plan view illustrating an example of a support member of the present embodiment.

FIG. 4 is a cross-sectional view taken along a line IV-IV illustrated in FIG. 3.

FIG. 5 is a view illustrating a positional relationship between the wafer boat and the support member according to the embodiment of the present disclosure.

FIG. 6 is a view illustrating a state where wafers and the support members are held on the wafer boat.

FIG. 7 is a view illustrating a configuration of a control unit.

FIG. 8A is a graph illustrating a ratio of a film formation amount in a rear surface of a support member to that in a front surface of the support member, in both cases of using the support member according to the embodiment of the present disclosure and using a support member having no wall.

FIG. 8B is a partially enlarged graph of FIG. 8A.

FIG. 9A is a graph illustrating a ratio of a film formation amount in a rear surface of a support member to that in a front surface of the support member, in both cases of using the support member according to the embodiment of the present disclosure and using a support member where an inner peripheral surface of a wall is not formed in a tapered shape.

FIG. 9B is a partially enlarged graph of FIG. 9A.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

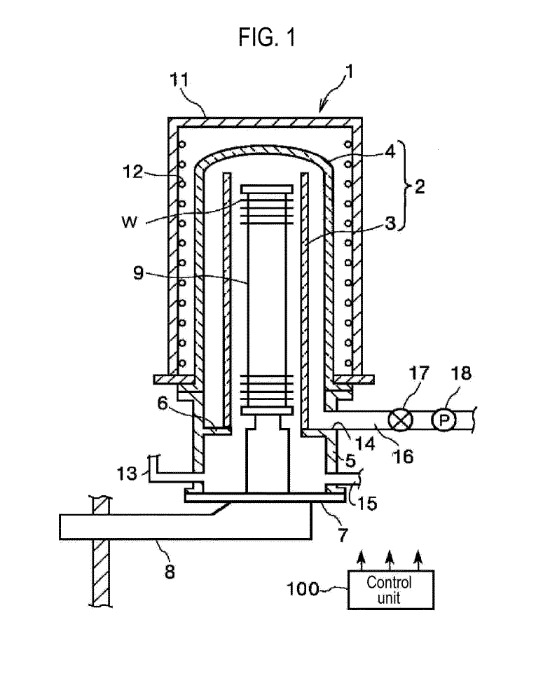

A support member of the present disclosure and a semiconductor manufacturing apparatus having the same will be described below. In this embodiment, an example of using a batch type vertical heat treatment apparatus illustrated in FIG. 1 as a semiconductor manufacturing apparatus will be described.

As illustrated in FIG. 1, a heat treatment apparatus 1 includes a reaction tube 2 having a substantially cylindrical shape in which a longitudinal side of the reaction tube 2 is extended in a vertical direction of the heat treatment apparatus 1. The reaction tube 2 has a double tube structure that includes an inner tube 3, and an outer tube 4 having a ceiling which covers the inner tube 3 and is formed to have a predetermined distance with the inner tube 3. The inner tube 3 and the outer tube 4 are formed of materials which are excellent in heat resistance and corrosion resistance, for example, quartz.

A manifold 5 made of stainless steel (SUS) formed in a cylindrical shape is disposed below the outer tube 4. The manifold 5 is hermetically connected to a lower end portion of the outer tube 4. Furthermore, the inner tube 3 is supported by a support ring 6 which protrudes from an inner wall of the manifold 5 and is integrated with the manifold 5.

A lid 7 is disposed below the manifold 5, and the lid 7 may be moved vertically by a boat elevator 8. Moreover, when the lid 7 is raised by the boat elevator 8, a lower side (a furnace port portion) of the manifold 5 is closed, and when the lid 7 is lowered by the boat elevator 8, the lower side (the furnace port portion) of the manifold 5 is opened.

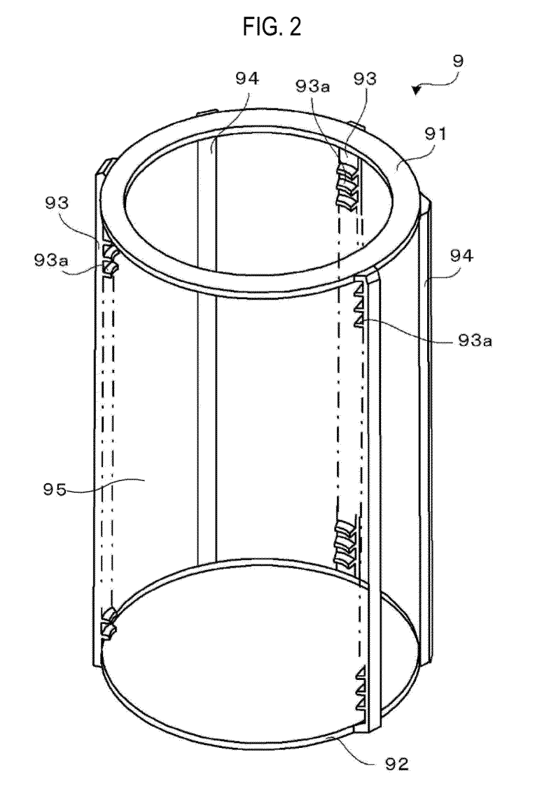

A wafer boat 9 made of, for example, quartz is mounted on the lid 7. The wafer boat 9 is configured to accommodate processing targets, for example, a plurality of wafers W at predetermined intervals in the vertical direction. The structure of the wafer boat 9 is illustrated in FIG. 2.

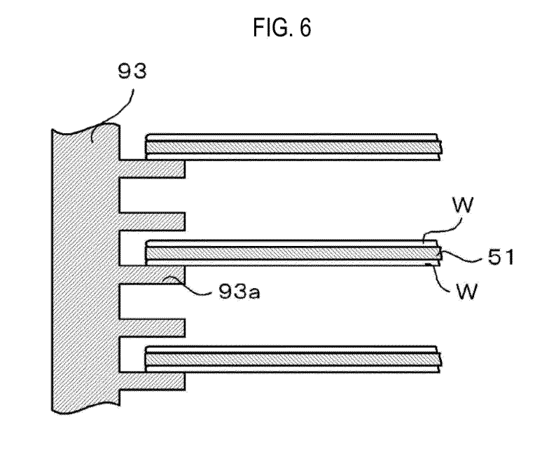

As illustrated in FIG. 2, the wafer boat 9 includes a top plate 91 and a bottom plate 92, and a plurality of, for example, three support pillars 93 are provided between the top plate 91 and the bottom plate 92. Auxiliary pillars 94 are installed between the support pillars 93. Furthermore, as illustrated in FIG. 6 to be described later, claw portions 93a for holding the wafers W and flat plates 51 of support members 50 configured to support the wafers W are installed in each of the support pillars 93 at predetermined intervals in the vertical direction. Each of the claw portions 93a projects toward the center of the wafer boat 9 and is formed to have a surface that is horizontal to the top plate 91 and the bottom plate 92. Furthermore, circular arc-shaped support plates may be installed between the support pillars 93 and the auxiliary pillars 94.

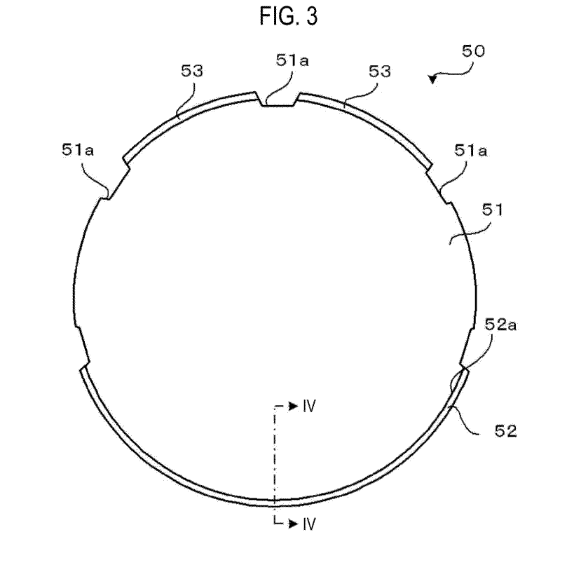

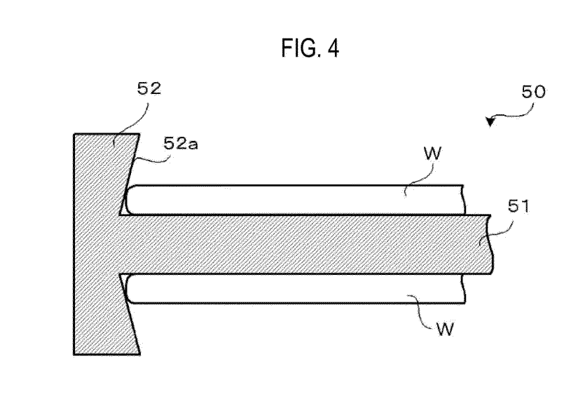

FIGS. 3 and 4 illustrate the structure of the support member 50 of the present disclosure. FIG. 3 is a plan view illustrating an example of the support member 50, and FIG. 4 is a cross-sectional view taken along a line IV-IV of FIG. 3.

As illustrated in FIGS. 3 and 4, the support member 50 includes the flat plate 51 and walls 52 and 53.

The flat plate 51 is a mounting portion configured to mount the processing targets thereon and is formed of, for example, a substantially circular flat plate-like member. The flat plate 51 is formed of, for example, quartz, SiC, silicon or the like. As illustrated in FIG. 4, the wafers W are mounted on one main surface and the other main surface of the flat plate 51. An outer diameter of the flat plate 51 is formed to be approximately equal to an outer diameter of the wafer W. The flat plate 51 may have a shape that can support the wafers W, and may be formed in, for example, a ring shape. Furthermore, notches 51a for use in transferring the wafers W are formed in an outer peripheral portion of the flat plate 51.

As illustrated in FIG. 3, the wall 52 is installed in a part of the outer peripheral portion of the flat plate 51 and is formed along the outer periphery of the flat plate 51. As illustrated in FIG. 4, the wall 52 is formed to be higher than a wafer among the wafers W held on the one main surface of the flat plate 51. Also, the wall 52 is formed to be higher than a wafer W among the wafers W held on the other main surface of the flat plate 51. That is to say, the wall 52 is formed to protrude in the vertical direction higher than the wafers W held on the main surfaces of the flat plate 51. The inner peripheral surface 52a of the wall 52 is formed in a shape capable of holding the wafers W disposed on the flat plate 51. In this embodiment, the inner peripheral surface 52a of the wall 52 is formed in a reverse tapered shape (tapered shape). Therefore, as illustrated in FIG. 4, the inner peripheral surface 52a of the wall 52 forms an acute angle with respect to the main surfaces of the flat plate 51. The inner peripheral surface 52a of the wall 52 may have a linear shape as illustrated in FIG. 4, or a curved shape. Further, a cross section of the wall 52 may be formed in a hook shape.

The wall 52 is installed in another part of the outer periphery of the flat plate 51, for example, approximately in a range of ¼ to ½ of the outer periphery of the flat plate 51, and is formed along the outer peripheral portion of the flat plate 51. The wafers W mounted on the support member 50 may be easily bent, particularly in a portion positioned in a wafer insertion port (opening) 95 of the wafer boat 9. Therefore, the wall 52 may be installed in a portion of the outer peripheral portion of the flat plate 51 corresponding to the opening 95 of the wafer boat 9. That is to say, the wall 52 is formed in a position, which is aligned with the opening 95 of the wafer boat 9 in a state where the support member 50 is inserted into the wafer boat 9.

As illustrated in FIG. 4, each of the wafers W is disposed so that a part of each of the wafers W is in contact with the inner peripheral surface 52a of the wall 52. Since a portion of the wall 52 in contact with the wafers W, i.e., the inner peripheral surface 52a of the wall 52 is formed in a tapered shape, it is possible to satisfactorily prevent the bending of the wafers W, as will be described later.

As illustrated in FIG. 3, at least the wall 53 is installed at a position facing the wall 52 and is formed along a portion of the outer peripheral portion of the flat plate 51. In the same manner as the wall 52, the wall 53 is formed to be higher than the wafer W held on one main surface of the flat plate 51 and to be higher than the wafer W held on the other main surface of the flat plate 51. That is to say, the wall 53 is formed to protrude in the vertical direction higher than the wafer W held on the main surfaces of the flat plate 51. The wall 53 may be omitted, and the inner peripheral surface of the wall 53 may not be formed in a tapered shape, but may be in various shapes.

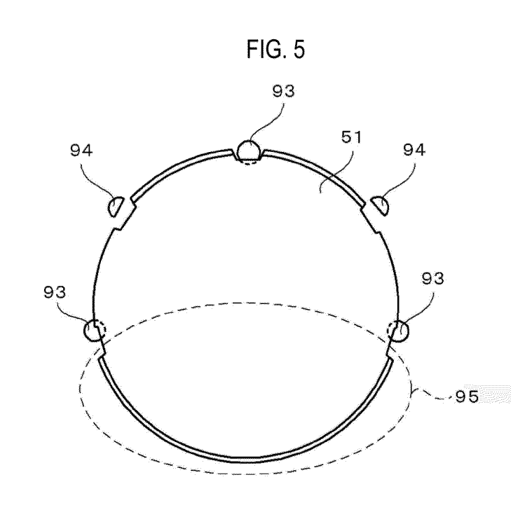

FIG. 5 illustrates a positional relationship among the support member 50, the support pillars 93 and the auxiliary pillars 94, when the support member 50 is installed on the wafer boat 9. In FIG. 5, for convenience of illustration, the support pillars 93 are shown as a circle, and the auxiliary pillars 94 are shown as a semicircle. Further, a portion denoted by a dashed line of FIG. 5 corresponds to the opening 95 of the wafer boat 9, and the support member 50 is inserted into the wafer boat 9 through the opening 95 in a direction from below to above. FIG. 6 illustrates a state where the wafers W and the support members 50 are supported on the wafer boat 9.

In a portion located on the inside of the opening 95 of the wafer boat 9, as illustrated in FIG. 6, the support members 50 (flat plates 51) and the wafers W are held by the support pillars 93 (claw portions 93a). Therefore, the wafers W are not easily bent. Meanwhile, in a portion corresponding to the opening 95 through which the wafers W are inserted, i.e., in a portion between the left and right support pillars 93 in FIG. 5, since the claw portions 93a are not provided below the support members 50, the support members 50 and the wafers W are not held by the claw portions 93a. Therefore, the wafers W are easily bent in the portion positioned in the opening 95, particularly, in a central portion of the opening 95, i.e., a lower portion of the wafer W in FIG. 5.

In this embodiment, the wall 52 is installed at a position corresponding to the opening 95, and as illustrated in FIG. 4, the inner peripheral surface 52a of the wall 52 is formed in a tapered shape (a shape capable of holding the wafers W). The installation of the wall 52 may prevent the bending of the wafers W even in the central portion of the opening 95. Therefore, it is possible to prevent an occurrence of wraparound of the film formation in the wafers W.

Referring back to FIG. 1, a heat insulating body 11 is installed to surround the reaction tube 2. Temperature-rising heaters 12 constituted by, for example, resistance heating elements are installed on an inner wall surface of the heat insulating body 11. The interior of the reaction tube 2 is heated to a predetermined temperature by the temperature-rising heaters 12, and as a result, the wafers W are heated to a predetermined temperature.

At least one processing gas introduction pipes 13 is inserted through (connected to) a side surface of the manifold 5. Only one processing gas introduction pipe 13 is illustrated in FIG. 1. The processing gas introduction pipe 13 is disposed to face the interior of the inner tube 3. For example, as illustrated in FIG. 1, the processing gas introduction pipe 13 is inserted through the side surface of the manifold 5 below the support ring 6 (below the inner tube 3).

The processing gas introduction pipe 13 is connected to a processing gas supply source (not illustrated) through a mass flow controller (not illustrated) or the like. Therefore, a desired amount of processing gas is supplied from the processing gas supply source into the reaction tube 2 through the processing gas introduction pipe 13.

An exhaust port 14 for exhausting the gas in the reaction tube 2 is formed on the side surface of the manifold 5. The exhaust port 14 is formed above the support ring 6 and communicates with a space between the inner tube 3 and the outer tube 4 of the reaction tube 2. The exhaust gas or the like generated in the inner tube 3 is discharged to the exhaust port 14 through the space between the inner tube 3 and the outer tube 4.

A purge gas supply pipe 15 is inserted below the exhaust port 14 through the side surface of the manifold 5. A purge gas supply source (not illustrated) is connected to the purge gas supply pipe 15, and a desired amount of purge gas, for example, nitrogen gas, is supplied from the purge gas supply source into the reaction tube 2 through the purge gas supply pipe 15.

An exhaust pipe 16 is hermetically connected to the exhaust port 14. A valve 17 and a vacuum pump 18 are installed in the exhaust tube 16 from an upstream side thereof. The valve 17 adjusts an opening degree of the exhaust pipe 16 to control the internal pressure of the reaction tube 2 to a predetermined pressure. The vacuum pump 18 exhausts the gas in the reaction tube 2 through the exhaust pipe 16 and also adjusts the internal pressure of the reaction tube 2.

A trap, a scrubber and the like (not illustrated) may be installed in the exhaust pipe 16 so that the gas exhausted from the reaction tube 2 can be detoxified and then discharged to the outside of the heat treatment apparatus 1.

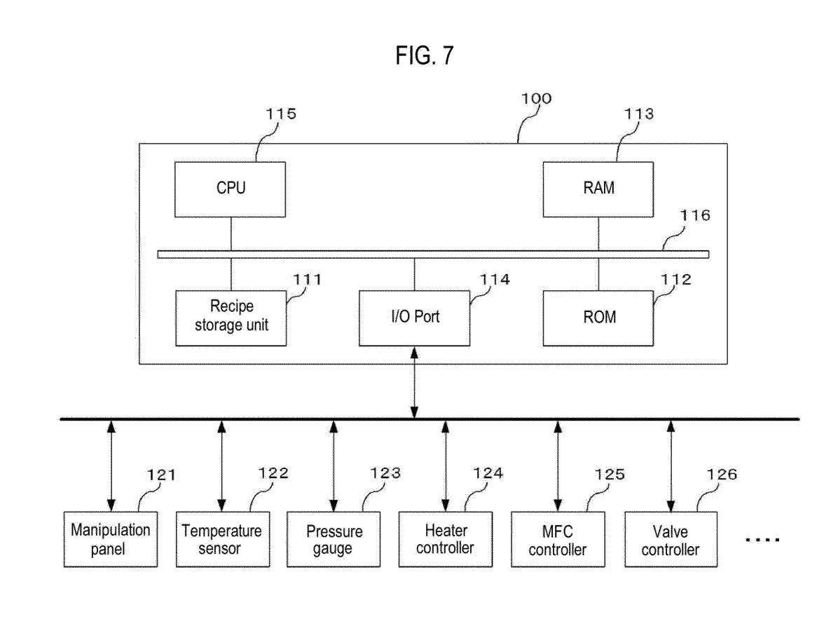

In addition, the heat treatment apparatus 1 includes a control unit 100 configured to control the respective parts of the heat treatment apparatus 1. FIG. 7 illustrates the configuration of the control unit 100. As illustrated in FIG. 7, a manipulation panel 121, a temperature sensor (group) 122, a pressure gauge (group) 123, a heater controller 124, an MFC (Mass Flow Controller) 125, a valve controller 126 and the like are connected to the control unit 100.

The manipulation panel 121 includes a display screen and manipulation buttons. The manipulation panel 121 transmits instructions from an operator to the control unit 100, and displays various types of information received from the control unit 100 on the display screen.

The temperature sensor (group) 122 measures the temperatures of each part such as the reaction tube 2, the processing gas introduction pipe 13 and the exhaust pipe 16, and notifies the measured temperatures to the control unit 100.

The pressure gauge (group) 123 measures the pressures of each part such as the reaction tube 2, the processing gas introduction pipe 13 and the exhaust pipe 16, and notifies the measured pressures to the control unit 100.

The heater controller 124 is configured to individually control the heaters 12. For example, the heater controller 124 may heat the heaters 12 by supplying electric current thereto in response to instructions from the control unit 100, and measures power consumption of the individual heaters 12 to notify the measurement results to the control unit 100.

The MFC 125 controls the MFCs (not illustrated) installed in the processing gas introduction pipe 13 and the purge gas supply pipe 15 to set flow rates of gases flowing through the processing gas introduction pipe 13 and the purge gas supply pipe 15 based on information (e.g., values) received from the control unit 100. The MFC 125 also measures flow rates of the actually flowing gases to notify the measurement results to the control unit 100.

The valve controller 126 adjusts the opening degrees of the valves installed in the respective pipes based on information (e.g., values) received from the control unit 100.

The control unit 100 includes a recipe storage unit 111, a ROM (Read Only Memory) 112, a RAM (Random Access Memory) 113, an I/O (Input/Output) port 114, a CPU (Central Processing Unit) 115, and a bus 116 that connects these components to one another.

The recipe storage unit 111 stores a setup recipe and a plurality of process recipes. At an initial stage of manufacturing the heat treatment apparatus 1, only the setup recipe is stored in the recipe storage unit 111. The setup recipe is executed when generating a thermal model or the like according to each heat treatment apparatus. The process recipe is a recipe prepared in every heat treatment (process) actually performed by an operator. According to the process recipe, the temperature of each part of the heat treatment apparatus 1 and/or the internal pressure of the reaction tube 2 may be adjusted. Further, the process recipe may provide start and stop timings of supplying processing gases, an amount of processing gas to be supplied or the like, for example, starting from when the wafers W are loaded into the reaction tube 2 until the processed wafers W are unloaded therefrom.

The ROM 112 is a recording medium that is constituted by an EEPROM (Electrically Erasable Programmable Read Only Memory), a flash memory, a hard disk or the like, and stores an operating program or the like of the CPU 115.

The RAM 113 serves as a work area or the like of the CPU 115.

The I/O port 114 is connected to the manipulation panel 121, the temperature sensor (group) 122, the pressure gauge (group) 123, the heater controller 124, the MFC 125, the valve controller 126 or the like to control the input and output of data and signals.

The CPU 115 constitutes the backbone of the control unit 100. The CPU 115 executes a control program stored in the ROM 112, and controls the operation of the heat treatment apparatus 1 based on the recipe (process recipe) stored in the recipe storage unit 111 according to the instructions received from the manipulation panel 121. That is, the CPU 115 instructs the temperature sensor (group) 122, the pressure gauge (group) 123, the MFC 125 and the like to measure the temperatures, the pressures, the flow rates and the like of the respective parts such as the reaction tube 2, the processing gas introduction pipe 13, the purge gas supply pipe 15 and the exhaust pipe 16. Then, the CPU 115 outputs control signals or the like to the heater controller 124, the MFC 125, the valve controller 126 and the like, based on the measurement data, to thereby control the respective parts based on the process recipe.

The bus 116 transmits information among the respective parts.

In order to confirm an effect of the heat treatment apparatus 1 having the support member 50 configured as described above, a silicon nitride film (SiN film) was formed on the wafers W using the heat treatment apparatus 1 having the support member 50. Specifically, wafers (Si substrates) W of 300 mm were accommodated in the wafer boat 9 while one wafer W was disposed on each of the front and rear surfaces of the support member 50, and then an SiN film was formed by a CVD (Chemical Vapor Deposition) method at 780 degrees C. After forming the SiN film on the wafers W, film thicknesses in the front surface and in the rear surface of the wafer W disposed on the rear surface of the support member 50 were measured linearly from the opening side toward the inside of the wafer boat 9 (from the bottom to the top in the example illustrated in FIG. 5). Then, a ratio (rear surface/front surface [%]) of the film thickness formed in the rear surface of the wafer W to the film thickness formed in the front surface of the wafer W at the same position was calculated.

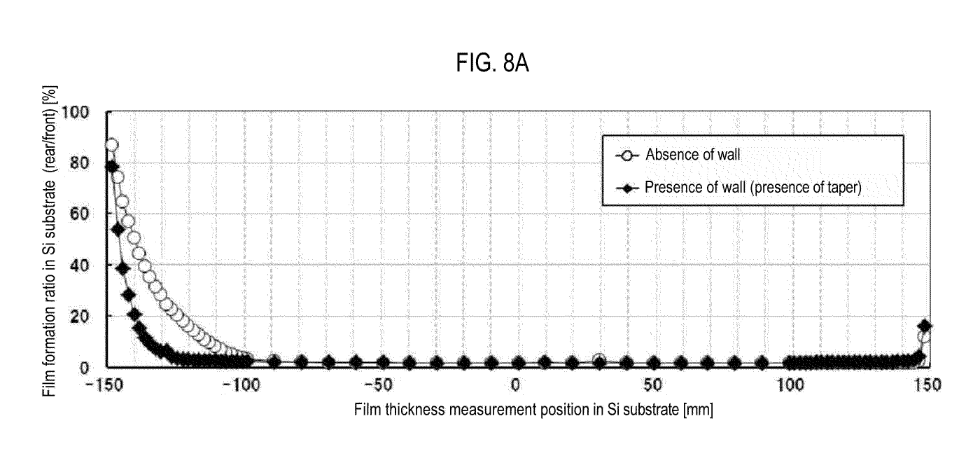

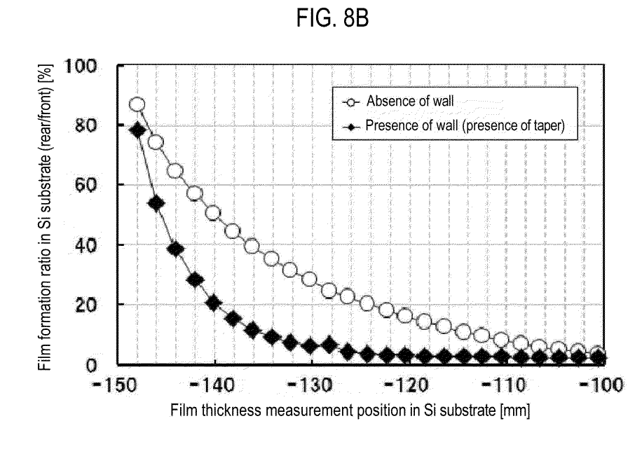

Similarly, for purpose of comparison, an SiN film was formed on the wafer W using a support member having no wall 52, and a ratio of the film thickness formed in the rear surface of the wafer W to the film thickness formed in the front surface of the wafer W at the same position was calculated. The results are shown in FIGS. 8A and 8B. In FIG. 8A, positions in the wafer (Si substrate) W are shown in a horizontal axis, and ratios of the film thicknesses (rear surface/front surface [%]) are shown in a vertical axis. In the horizontal axis of FIG. 8A, a center of a wafer W was expressed as 0 mm, a periphery of the wafer W at the opening side was expressed as −150 mm, and a periphery of the wafer W at the inside of the wafer boat 9 was expressed as 150 mm. FIG. 8B illustrates an enlarged view of the range from −150 mm to −100 mm at the opening side where an abnormal film formation in the rear surface of the wafer W causes a problem.

As illustrated in FIGS. 8A and 8B, in a case of using the support member having no wall 52, a wraparound amount of the film formation to the rear surface of the wafer W was about 50% at a position of 10 mm from the periphery of the wafer W (denoted as −140 mm in FIG. 8A) and was about 20% at a position of 25 mm from the periphery of the wafer W (denoted as −125 mm in FIG. 8A). In contrast, in a case of using the support member 50 provided with the wall 52, a significant improvement was shown, and the wraparound amount of 20% was observed at a position of 10 mm from the periphery of the wafer W (denoted as −140 mm in FIG. 8A).

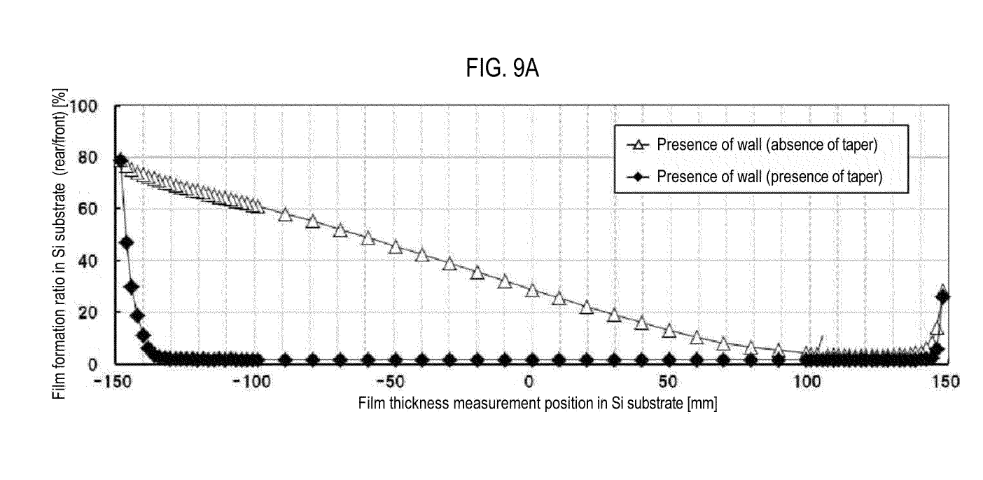

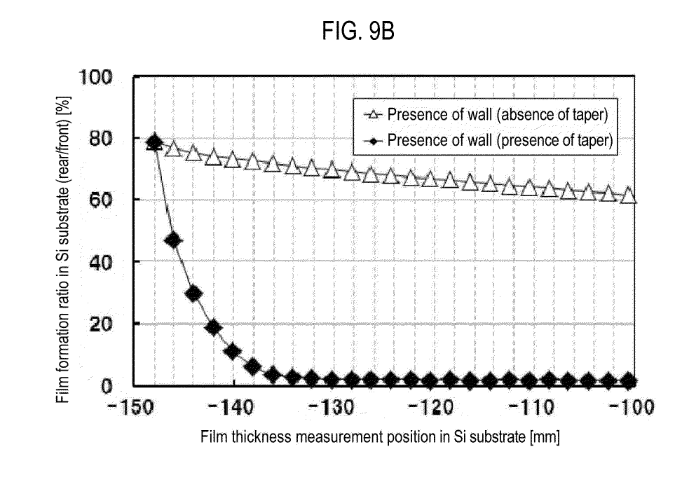

Next, SiN films were formed on the wafers W using a heat treatment apparatus having a support member where the inner peripheral surface 52a of the wall 52 is not formed in a tapered shape (a shape capable of holding the wafer W) and a heat treatment apparatus having the support member 50 where the inner peripheral surface 52a of the wall 52 is formed in a tapered shape according to the above described embodiment. Further, for each heat treatment apparatuses, a ratio of a film thickness formed in the rear surface of the wafer W to a film thickness formed in the front surface of the wafer W at the same position was calculated. The results are shown in FIGS. 9A and 9B. Here, the expression “the inner peripheral surface 52a of the wall 52 is not formed in a tapered shape” means that the inner peripheral surface 52a of the wall 52 is installed so as to be substantially perpendicular to the main surface of the flat plate 51 of the support member 50.

As illustrated in FIG. 9A, in a case of using a support member where the inner peripheral surface 52a of the wall 52 is not formed in a tapered shape (Δ presence of wall (absence of taper)), a film is formed in the rear surface of the wafer W to a position of 250 mm from the periphery of the wafer W at the opening side (denoted as 100 mm in FIG. 9A), and a considerable wraparound amount of the film formation of 30% could be confirmed in the center of the wafer W. Such considerable wraparound amount may be due to the periphery of the wafer W at the opening side climbing the wall 52 when the heat treatment is performed in a state where the periphery of the wafer W at the opening side comes into contact with the wall 52. Meanwhile, in a case of using the support member 50 where the inner peripheral surface 52a of the wall 52 is formed in a tapered shape (♦ presence of wall (presence of taper)) according to the above-described embodiment, a tendency of climbing the wall 52 is not observed even when the heat treatment is performed in a state where the periphery of the wafer W at the opening side comes into contact with the wall 52. This is because the tapered shape of the inner peripheral surface 52a has an effect of preventing the climbing of the periphery of the wafer W during thermal expansion of the wafer W, and the expansion of the wafer W can be avoided in a direction opposite to the wall 52. As illustrated in FIG. 9B, from the fact that the film formation ratio reaches almost zero at a position of −135 mm, it confirmed that there is a significant effect of preventing the wraparound of the film formation to the rear surface of the wafer W by using the wall 52 having the inner peripheral surface 52a formed in a tapered shape.

In FIGS. 8A, 8B, 9A, and 9B, the ratio of the film thickness formed in the rear surface of the wafer W to the film thickness formed in the front surface of the wafer W at the same position was calculated with respect to the wafers W disposed on the rear surface of the support member 50.

However, the same measurement was performed on the wafers W disposed on the front surface of the support member 50, and it was confirmed that the same results as those of the wafer W disposed on the rear surface of the support member 50 are obtained.

As described above, according to this embodiment, by forming the inner peripheral surface 52a of the wall 52 of the support member 50 in a shape capable of holding the wafer W (tapered shape), it is possible to prevent the bending of the wafer W, thereby preventing an occurrence of wraparound of the film formation in the wafer W.

Furthermore, the present disclosure can be variously modified and applied without being limited to the above-described embodiment. Hereinafter, other embodiments capable of being applied to the present disclosure will be described.

In the above-described embodiment, the present disclosure has been described as an example of a case where the inner peripheral surface 52a has a tapered shape (reverse tapered shape). However, the inner peripheral surface 52a is not limited to the tapered shape, and may have other shapes capable of holding the wafers W. For example, the inner peripheral surface 52a may have a curved shape or a hook shape.

In the above-described embodiment, the present disclosure has been described as an example of a case where both main surfaces of the support member 50 have the wall 52 having the inner peripheral surface 52a formed in a tapered shape. However, for example, only one main surface may have a wall 52 having an inner peripheral surface 52a formed in a tapered shape. Alternatively, the wall 52 may be formed on both main surfaces, and the inner peripheral surface 52a at the side of only one of the main surfaces may be formed in a tapered shape.

In the above-described embodiment, the present disclosure has been described as an example of a case where the flat plate 51 is used as a mounting unit configured to mount the wafers W thereon. However, the mounting unit may have other shape that can support the wafers W, and may be formed in, for example, a ring shape.

In the above-described embodiment, the present disclosure has been described as an example of a case where the flat plate 51 and the wall 52 are integrated. However, for example, the flat plate 51 and the wall 52 may be separate parts and combined with each other.

In the above-described embodiment, the present disclosure has been described as an example of a case where the continuous wall 52 is installed between the support pillars 93. However, a plurality of walls rather than the continuous one wall 52 may be installed between the support pillars 93.

In the above-described embodiment, the present disclosure has been described as an example of a case where a batch type vertical heat treatment apparatus of a double tube structure is used as the heat treatment apparatus. However, the present disclosure may be also applied to, for example, a batch type heat treatment apparatus of a single tube structure.

The control unit 100 according to the embodiment of the present disclosure may be implemented using a normal computer system rather than using a dedicated system. For example, the control unit 100 may be configured to perform the above-described process, by installing a program for executing the above-described process into a general-purpose computer from a recording medium (a flexible disk, a CD-ROM (Compact Disc Read Only Memory) or the like) storing the program.

Moreover, means for supplying the programs is arbitrary. For example, other than supplying the program via a predetermined recording medium as described above, the program can be supplied via a communication line, a communication network, a communication system or the like. In this case, for example, the program may be posted in a BBS (Bulletin Board System) on a communication network and may be provided by being superimposed on a carrier wave via a network. The above-described process can be executed by starting the program provided in this way and executing the program similarly to other application programs under the control of OS (Operating System).

According to the present disclosure, it is possible to provide a support member capable of preventing the bending of the substrate during film formation, particularly, during heat treatment, and a semiconductor manufacturing apparatus having the same.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A support member comprising:
a mounting unit having a first main surface and a second main surface, the first main surface being configured to mount a first object to be processed thereon and the second main surface being configured to mount a second object to be processed thereon; and
a wall installed in a part of an outer peripheral portion along the outer periphery of the mounting unit, the wall having a first portion protruding in a vertical direction higher than the first object to be processed mounted on the first main surface of the mounting unit,
wherein an inner peripheral surface of the first portion of the wall is formed in a first shape that allows the first object to be held by the first portion of the wall.

2. The support member of claim 1, wherein the wall has a second portion protruding in the vertical direction higher than the second object to be processed mounted on the second main surface of the mounting unit, and
wherein the inner peripheral surface of the second portion of the wall is formed in a second shape that allows the second object to be processed to be held by the second portion of the wall.

3. The support member of claim 1, wherein the first shape is a tapered shape.

4. The support member of claim 2, wherein the second shape is a tapered shape.

5. The support member of claim 2, wherein the first shape and the second shape are a tapered shape.

6. A semiconductor manufacturing apparatus comprising:
the support member of claim 1; and
a holding member configured to hold the support member, the holding member having an opening through which the supported member is inserted into the holding member.

7. The semiconductor manufacturing apparatus of claim 6, wherein the wall of the support member is formed at a position, which is aligned with the opening of the holding member in a state where the support member is inserted into the holding member.

8. The semiconductor manufacturing apparatus of claim 6, wherein the wall has a second portion protruding in the vertical direction than the second object to be processed mounted on the second main surface of the mounting unit, and
wherein the inner peripheral surface of the second portion of the wall is formed in a second shape that allows the second object to be processed to be held by the second portion of the wall.

9. The semiconductor manufacturing apparatus of claim 6, wherein the first shape is a tapered shape.

10. The semiconductor manufacturing apparatus of claim 8, wherein the second shape is a tapered shape.

11. The semiconductor manufacturing apparatus of claim 8, wherein the first shape and the second shape is a tapered shape.
